(19) United States
(12) Patent Application Publication
(10) Pub. No.: US 2001/0023942 A1
(43) Pub. Date: Sep. 27, 2001

(54) Semiconductor device of heterojunction structure having quantum dot buffer layer

(75) Inventors: Moon-Deock Kim, Yongin-city (KR); Seong-Guk Lee, Yongin-city (KR)

Correspondence Address: STEVE S. CHA, ESQ., KLAUBER & JACKSON, 411 HACKENSACK AVENUE, HACKENSACK, NJ, 07601, US

(73) Assignee: SAMSUNG ELECTRONICS CO., LTD.

(21) Appl. No.: 09/809,934

(22) Filed: Mar. 16, 2001

(30) Foreign Application Priority Data
Mar. 23, 2000 (KR) 00-14820

(51) Int. Cl. H01L 29/06; H01L 31/0328; H01L 31/0336; H01L 31/072; H01L 31/109

(52) U.S. Cl. 257/14; 257/15

(57) ABSTRACT

A semiconductor device with a heterojunction structure having a substrate and a crystal layer which is grown over the substrate, in which a quantum dot buffer layer is interposed between the substrate and the crystal layer. In the semiconductor device, the interposition of the quantum dot buffer layer between the substrate and the crystal layer can effectively eliminate lattice mismatch between the substrate and the crystal layer. Therefore, a semiconductor device having excellent electro-optical characteristics can be obtained.

### CLAIM OF PRIORITY

This application makes reference to, incorporates the same herein, and claims all benefits accruing under 35 U.S.C. Section 119 from an application for SEMICONDUCTOR DEVICE OF HETEROJUNCTION STRUCTURE HAVING QUANTUM DOT BUFFER LAYER filed in the Korean Industrial Property Office on Mar. 23, 2000 and there duly assigned Ser. No. 2000-14820.

### BACKGROUND OF THE INVENTION

1. Field of the Invention

The present invention relates to a semiconductor heterojunction structure with having a quantum dot buffer layer.

2. Description of the Related Art

In general, when two different semiconductor materials are used to form a junction, the junction is called a semiconductor heterojunction. As the two materials used to form a heterojunction will have different energy bandgaps, the energy band will have a discontinuity at the junction interface. In order to have a useful heterojunction, the lattice constants of the two materials must be well matched. To this end, a buffer layer for compensating for lattice mismatch is typically interposed between a substrate layer and a crystal layer in a semiconductor device. A buffer layer is a flat thin film and has a limited capabilities in compensating the lattice mismatch, thus resulting in degradation of the performance of semiconductor devices.

Accordingly, there is a need to improve a double heterojunction structure to better compensate the undesirable lattice mismatch.

### SUMMARY OF THE INVENTION

An objective of the present invention is to provide a semiconductor device having a buffer layer capable of effectively reducing lattice mismatch between a substrate and a crystal layer.

To achieve the above objective, the present invention provides a heterojunction semiconductor structure having a quantum dot buffer layer, wherein the quantum dot buffer layer is interposed between a substrate layer and a crystal layer that is grown over the substrate.

Preferably, a buffer layer having a quantum dot structure is formed by using a molecular beam epitaxy (MBE) process, chemical vapor deposition (CVD) process, vapor phase epitaxy (VPE) process, or liquid phase epitaxy (LPE) process.

Preferably, sapphire, Si or a III-V compound semiconductor containing GaAs, InP or the like is used as the substrate.

Preferably, when the substrate is formed of GaAs, the quantum dot buffer layer is formed of a III-V family compound selected from GaN, GaAs, GaSb, InAs, InAlAs, InGaAs and GaAlSb.

Preferably, when the substrate is formed of InP, the quantum dot buffer layer is formed of a III-V family compound selected from InAs, InSb, InGaN, InGaAs, InAlAs and GaInSb.

Preferably, when the substrate is formed of sapphire, the quantum dot buffer layer is formed of a III-V family compound selected from AlN and InAlN.

Preferably, when the substrate is formed of Si, the quantum dot buffer layer is formed of a compound among III-V family and IV-IV family compounds, such as InAs, GaAs, InGaAs, InAlAs and SiGe.

### BRIEF DESCRIPTION OF THE DRAWINGS

The above objective and advantage of the present invention will become more apparent by describing in detail preferred embodiments thereof with reference to the attached drawings in which:

FIG. 1 illustrates a first embodiment of a semiconductor device according to the present invention;

FIG. 2 illustrates a second embodiment of a semiconductor device according to the present invention;

FIG. 3 illustrates a third embodiment of a semiconductor device according to the present invention;

FIG. 4 illustrates a fourth embodiment of a semiconductor device according to the present invention;

FIG. 5 is an atomic force microscopy (AFM) image of an AlN quantum dot buffer layer generated after flowing ammonia gas onto the sapphire substrate layer according to the first embodiment of the present invention of FIG. 1;

FIG. 6 is a line diagram showing a variation in lattice parameter during the formation of the AlN quantum dot buffer layer of FIG. 5;

FIG. 7 is a picture of the surface of a GaN crystal layer formed on an AlN quantum dot buffer layer on a sapphire substrate layer according to the first embodiment of the present invention of FIG. 1;

FIG. 8 is a picture of the surface of a sample of a GaN thin film to which a quantum dot buffer layer according to the present invention is not applied;

FIG. 9 is a double crystal X-ray deflectormeter (DXRD) line diagram showing the comparison of the samples of FIGS. 7 and 8;

FIG. 10 is an AFM picture of a GaAs substrate on which an InAs quantum dot buffer layer is formed according to the second embodiment of the present invention of FIG. 2; and,

FIG. 11 is a line diagram showing the variation in lattice parameter obtained by a variation in the reflection high energy electron diffraction (RHEED) structure when an InAs quantum dot buffer layer is formed onto a GaAs substrate layer according to the fourth embodiment of the present invention of FIG. 4.

### DETAILED DESCRIPTION OF THE PREFERRED EMBODIMENTS

According to the embodiment of the present invention, a heterojunction semiconductor material includes a crystal layer of GaN, In_{1-X}Al_{X}As, In_{1-X}Ga_{X}As, or GaAs which is formed on a substrate of Sapphire, Si, GaAs, or InP. The density defects generated by lattice mismatch between the substrate and the crystal layer are compensated by a buffer layer including a quantum dot structure.

The quantum dots on the buffer layer are formed in the form of discrete islands on the substrate layer. The formation of quantum dot structure is controlled by a strain energy formed by the hetrojunction interface. The formation of quantum dots on such a strained heterojunction system does not require a patterning process and is inherently free from damages.

In the present invention as described above, the quantum dot structure is formed readily and with reliability by using an MBE (Molecular Beam Epitaxy) process, vapor phase epitaxy (VPE) or liquid phase epitaxy (LPE), or an CVD (Chemical Vapor Deposition) process such that a very thin quantum buffer layer is sandwiched between a pair of barrier layers. The interposition of a quantum dot buffer layer that is constructed between a substrate and a crystal layer according to the present invention can effectively eliminate lattice mismatch between the substrate and the crystal layer.

A buffer layer is grown in several mono-layers pseudomorphically with a lattice parameter that matches with the lattice parameter of a substrate in the early stage of generation. Then, quantum dots are formed therein to reduce any deformation caused by the lattice mismatch. When the conditions of growth of a buffer layer are controlled after or right before quantum dots are generated, the buffer layer has a lattice parameter that is similar to the material of a crystal layer grown on a substrate. As a result, the number of defects generated by lattice mismatch can be reduced.

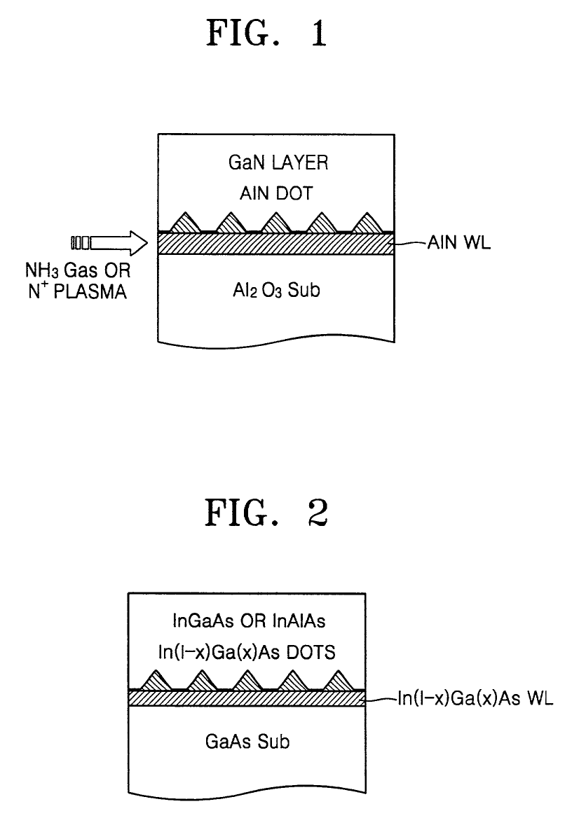

FIGS. 1-4 represent sectional view of different embodiments of a semiconductor material according to the present invention. WL in the drawings denotes a wetting layer.

Referring to FIG. 1, according to one embodiment of the present invention, ammonia gas or nitrogen plasma is laterally applied on a sapphire substrate to form AlN quantum dots thereon, then a GaN crystal layer is grown on the resultant structure. In this layered structure, the AlN quantum dot layer helps to reduce the undesirable lattice mismatch. The quantum dot layer may be formed of III-V family compound, i.e., AlN and InAlN.

According to the second embodiment of the present invention, if nitrogen plasma is sprayed on a GaAs substrate, a GaN quantum dot thin film without defects can be obtained. If a thin film of In_{0.52}Al_{0.48}As or In_{0.53}Al_{0.47}As is grown directly on the GaAs substrate, there is 3.8% of lattice mismatch. Thus, a lot of defects are generated during the manufacture of optical, electronic devices. These problems can be solved by using an In_{1-X}Ga_{X}As (where x is variable between 0 and 1) quantum dot buffer layer to remove mismatch, as shown in FIG. 2.

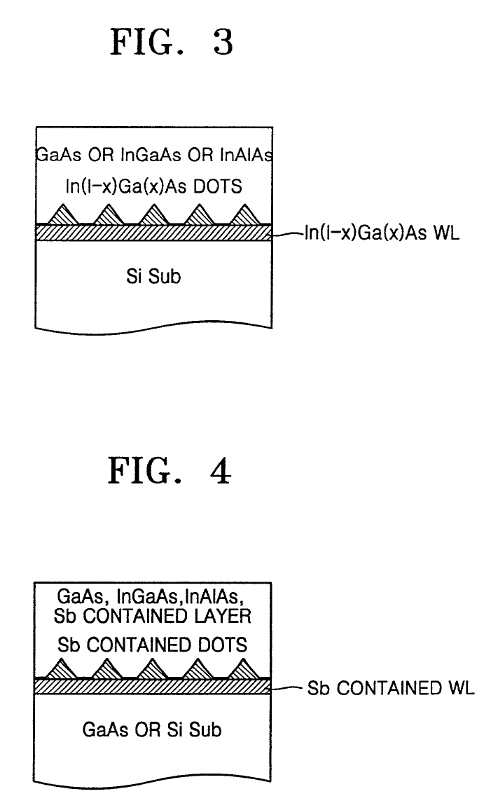

Referring to FIG. 3, according to the third embodiment of the present invention, a GaAs, InGaAs, or InAlAs thin film is formed over an Si substrate during manufacture of semiconductor devices. Here, the quantum dot buffer layer is formed of at least one compound selected from a group consisting of III-V family and IV-IV family compounds which includes InAs, GaAs, InGaAs, InAlAs and SiGe. Accordingly, defects due to lattice mismatch can be reduced by using the above-described GaAs or In_{1-X}Ga_{X}As quantum dot buffer layer.

Referring to FIG. 4, according to the forth embodiment of the present invention, 4, an Sb-contained quantum dot buffer layer is formed over a GaAs or Si substrate, and a crystal layer containing GaAs, InGaAs, InAlAs, GaAsSb, InGaAsSb or InAlAsSb is then grown. Here, the substrate can be formed of InP, and the same material as that of the quantum dot buffer layer formed on the GaAs and Si substrate can be formed on the InP substrate. However, the composition ratio of the elements of the quantum dot buffer layer has to changed depending on the type of the substrate material (GaAs, Si or InP). As a result, defects due to lattice mismatch can be reduced.

Now, a discussion of the advantages obtained from the respective embodiment is described hereinafter.

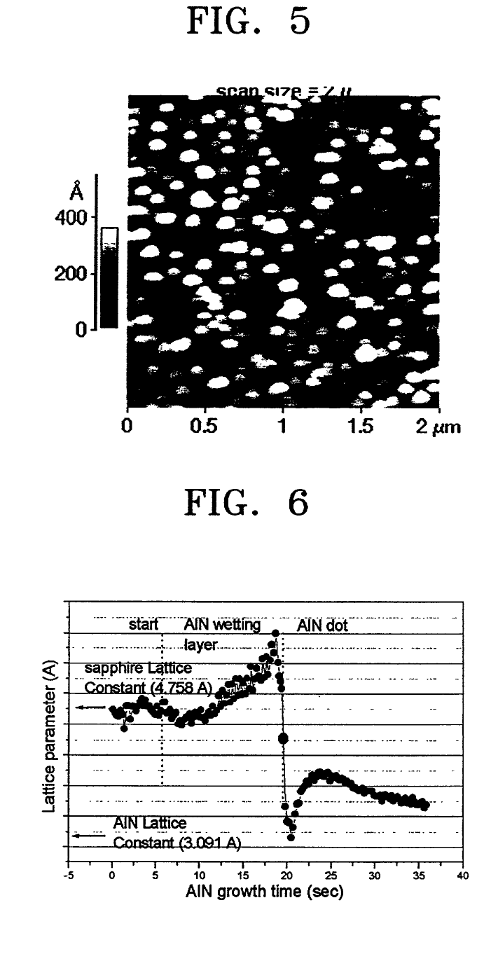

FIG. 5 is an AFM image of an AlN quantum dot buffer layer formed on a sapphire substrate of FIG. 1. If the amount of ammonia gas NH₃ and a reaction temperature, i.e., the substrate temperature during the crystal growth process, are appropriately controlled, the size of each quantum and the density of quantum dots can be controlled. These AlN quantum dots are formed having a variation in lattice parameter, as shown in FIG. 6. As can be seen from FIG. 6, after quantum dots are formed to have the lattice constant of AlN as shown in FIG. 5. Accordingly, if a GaN crystal layer is grown on the these quantum dots, the density of defects is significantly reduced.

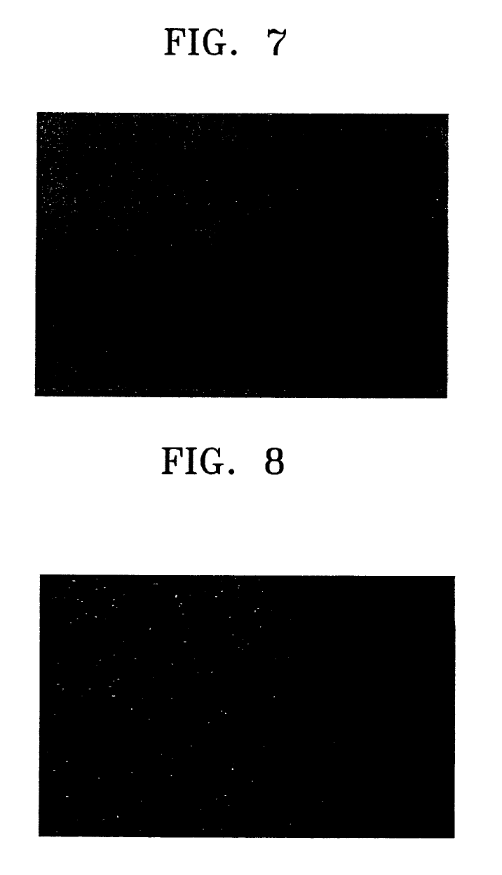

FIGS. 7 and 8 are comparison surface pictures of a GaN thin film formed on a substrate, as shown in FIG. 1, on which the AlN quantum dot buffer layer has been formed, and a GaN thin film on a substrate on which an AlN quantum dot buffer layer is not formed, respectively. As shown in FIG. 7, a GaN thin film, to which a quantum dot buffer layer has been applied, has a very excellent surface such as a mirror surface. In contrast, it can be seen from FIG. 8 that a GaN thin film grown directly on a substrate, without the AlN quantum dot layer has a very rough surface.

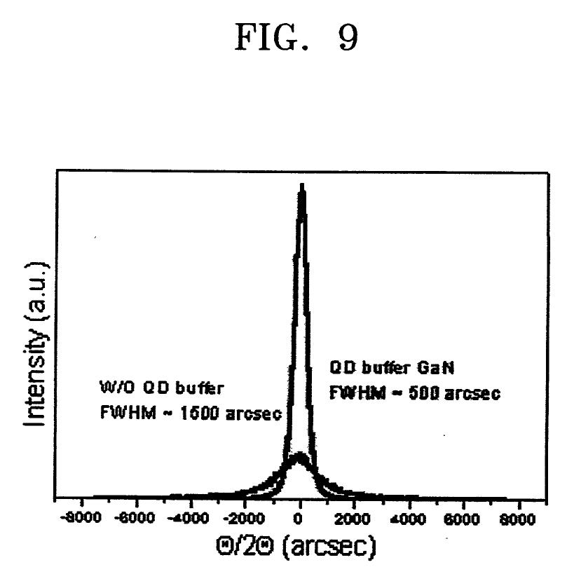

As shown in FIG. 9 showing the double crystal X-ray deflectormeter (DXRD) results with respect to the two respective thin film of FIGS. 7 and 8, the sample the GaN layer with an AlN quantum dot buffer layer, to which an AlN quantum dot buffer layer is applied, has good characteristics.

FIG. 10 is an AFM picture of a GaAs substrate observed after an InAs or In(Ga)As quantum dot buffer layer is formed on the GaAs substrate as shown in FIG. 2. Likewise, the sizes of each quantum dot and the density of quantum dots can be controlled by appropriately adjusting the ratio of a V-family component to a III-family component and the growing temperature. As the number of quantum dots increases, a thin film formed on the quantum dots has better characteristics.

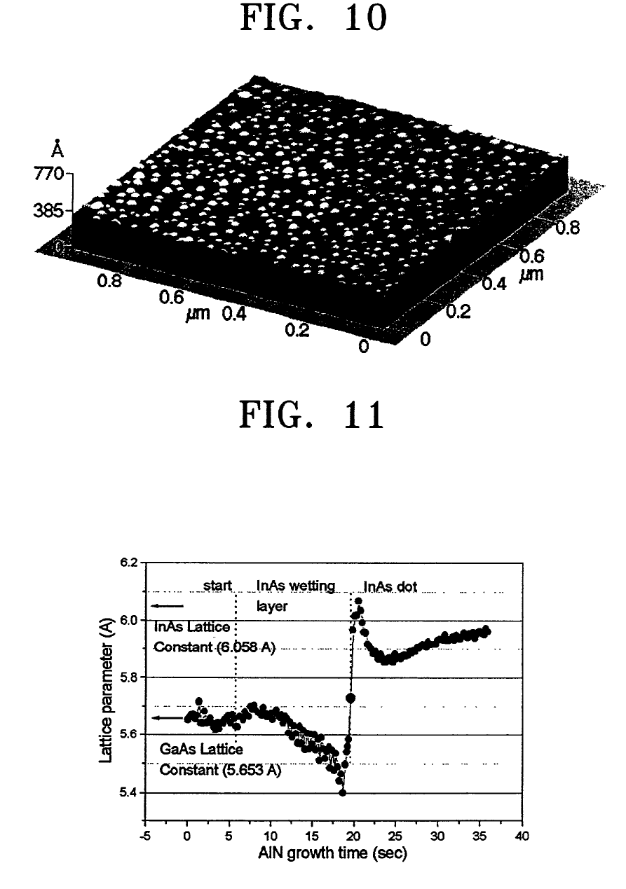

FIG. 11 shows a variation of the lattice constant of InAs quantum dots grown on a GaAs substrate. If Ga is added to InAs, InGaAs quantum dots are formed. At this time, if the amount of Ga is added to InAs in controlled so that the lattice constant of InGaAs matches wtih the lattice constant of the InP sibstrate, an InAlAs or InGaAs crystal layer can be grown directly on the GaAs substrate. After forming the buffer layer, eletrical and optical devices structures can be grown on the buffer layer.

The present invention is applicable to heterojunction structures such as blue laser using GaN, optical communication and electronic devices with an InGaAs or InAlAs structure based on a GaAs and InP substrate, and optical electronic structures where a GaAs, InGaAs or InAlAs crystal layer is formed on an Si substrate, so that lattice mismatching caused during the crystal growth can be greatly eliminated by a quantum dot buffer layer that is constructed according to the present invention.

In the present invention as described above, the quantum dots can be formed by molecular beam epitaxy (MBE), chemical vapor deposition (CVD), vapor phase epitaxy (VPE) or liquid phase epitaxy (LPE). Also, the interposition of a quantum dot buffer layer between a substrate and a crystal layer can effectively eliminate lattice mismatch between the substrate and the crystal layer. Therefore, a semiconductor device having excellent electro-optical characteristics can be obtained.

Although the invention has been described with reference to the particular embodiments shown in the drawings, it will be apparent to one of ordinary skill in the art that modifications to the described embodiments may be made without departing from the spirit and scope of the invention.

What is claimed is:

1. A semiconductor device with a heterojunction structure, comprising:
a substrate;
a quantum dot buffer layer formed on said substrate; and,
a crystal layer formed on said quantum dot buffer layer;
wherein said quantum dot buffer layer is interposed between said substrate and said crystal layer.

2. The semiconductor device of claim 1, wherein said quantum dot buffer layer is formed by one of molecular beam epitaxy (MBE) process, chemical vapor deposition (CVD) process, vapor phase epitaxy (VPE) process, and liquid phase epitaxy (LPE) process.

3. The semiconductor device of claim 1, wherein said substrate comprises at least one layer of III-V group compound semiconductor containing GaAs and InP compound layer.

4. The semiconductor device of claim 1, wherein said substrate comprises at least one layer of sapphire and Si compound.

5. The semiconductor device of claim 3, wherein said quantum dot buffer layer is formed of at least one III-V family compound selected from a group consisting of GaN, GaAs, GaSb, InGaAs and GaAlSb if said substrate is formed of GaAs.

6. The semiconductor device of claim 3, wherein said crystal layer comprises at least one of InGaAs and InAlAs compound if said substrate is formed of GaAs.

7. The semiconductor device of claim 3, wherein said quantum dot buffer layer is formed of at least one III-V family compound selected from a group consisting of InAs, InSb, InGaAs, InAlAs and GaInSb if said substrate is formed of InP.

8. The semiconductor device of claim 3, wherein said crystal layer comprises at least one of GaAs, InGaAs, InAlAs, and Sb compound if said substrate is formed of InP.

9. The semiconductor device of claim 4, wherein said quantum dot buffer layer is formed of at least one III-V family compound selected from a group consisting of AlN, InAlN and GaN if said substrate is formed of said sapphire.

10. The semiconductor device of claim 4, wherein said crystal layer comprises GaN layer if said substrate is formed of said sapphire.

11. The semiconductor device of claim 4, wherein said quantum dot buffer layer is formed of at least one compound selected from a group consisting of III-V family and IV-IV family compounds which includes InAs, GaAs, InGaAs, InAlAs and SiGe if said substrate is formed of Si.

12. The semiconductor device of claim 4, wherein said crystal layer comprises at least one of GaAs, InGaAs, and InAlAs compound if said substrate is formed of Si.

13. A semiconductor device with a heterojunction structure, comprising:
a substrate having at least one layer of Ill-V group compound semiconductor containing GaAs and InP compound layer;
a quantum dot buffer layer formed on said substrate; and,
a crystal layer formed on said quantum dot buffer layer;
wherein said quantum dot buffer layer is interposed between said substrate and said crystal layer.

14. The semiconductor device of claim 13, wherein said quantum dot buffer layer is formed of at least one III-V family compound selected from a group consisting of GaN, GaAs, GaSb, InGaAs and GaAlSb if said substrate is formed of GaAs.

15. The semiconductor device of claim 13, wherein said crystal layer comprises at least one of InGaAs and InAlAs compound if said substrate is formed of GaAs.

16. The semiconductor device of claim 13, wherein said quantum dot buffer layer is formed of at least one III-V family compound selected from a group consisting of InAs, InSb, InGaAs, InAlAs and GaInSb if said substrate is formed of InP.

17. The semiconductor device of claim 13, wherein said crystal layer comprises at least one of GaAs, InGaAs, InAlAs, and Sb compound if said substrate is formed of InP.

18. The semiconductor device of claim 13, wherein said quantum dot buffer layer is formed by one of molecular beam epitaxy (MBE) process, chemical vapor deposition (CVD) process, vapor phase epitaxy (VPE) process, and liquid phase epitaxy (LPE) process.

19. A semiconductor device with a heterojunction structure, comprising:
a substrate having at least one layer of sapphire and Si compound.
a quantum dot buffer layer formed on said substrate; and,
a crystal layer formed on said quantum dot buffer layer;
wherein said quantum dot buffer layer is interposed between said substrate and said crystal layer.

20. The semiconductor device of claim 19, wherein said quantum dot buffer layer is formed of at least one III-V family compound selected from a group consisting of AlN, InAlN and GaN if said substrate is formed of said sapphire.

21. The semiconductor device of claim 19, wherein said crystal layer comprises GaN layer if said substrate is formed of said sapphire.

22. The semiconductor device of claim 19, wherein said quantum buffer dot buffer layer is formed of at least one compound selected from a group consisting of III-V family and IV-IV family compounds which includes InAs, GaAs, InGaAs, InAlAs and SiGe if said substrate is formed of Si.

23. The semiconductor device of claim 19, wherein said crystal layer comprises at least one of GaAs, InGaAs, and InAlAs compound if said substrate is formed of Si.

24. The semiconductor device of claim 19, wherein said quantum dot buffer layer is formed by one of molecular beam epitaxy (MBE) process, chemical vapor deposition (CVD) process, vapor phase epitaxy (VPE) process, and liquid phase epitaxy (LPE) process.
